(19) United States
(12) Patent Application Publication
(10) Pub. No.: US 2026/0265062 A1
(43) Pub. Date: Sep. 10, 2026

(54) ELECTRON SPIN CONTAINING MATERIALS AND METHODS FOR PRODUCING SAID MATERIALS

(71) Applicant: ARCHER MATERIALS LIMITED, Adelaide (AU)

(72) Inventors: Solomon Freer, Adelaide (AU); Martin Fuechsle, Adelaide (AU); Alexander Porkovich, Adelaide (AU); Marta Sanchez Miranda, Adelaide (AU); Angela Tanesha, Adelaide (AU); Jun Zhang, Adelaide (AU)

(21) Appl. No.: 19/491,302

(22) PCT Filed: Jun. 7, 2024
(86) PCT No.: PCT/AU2024/050606

§ 371 Date: Dec. 8, 2025

(30) Foreign Application Priority Data
Jun. 9, 2023 (AU) 2023901839

(51) Int. Cl. C01B 32/15; B82Y 10/00; B82Y 40/00; C23C 16/30; C23C 16/34; C23C 16/40; C23C 16/44; C23C 16/56; G06N 10/40; H10N 99/00

(52) U.S. Cl. CPC C01B 32/15; B82Y 10/00; B82Y 40/00; C23C 16/308; C23C 16/342; C23C 16/345; C23C 16/402; C23C 16/403; C23C 16/405; C23C 16/4417; C23C 16/56; G06N 10/40; H10N 99/05; C01P 2002/54; C01P 2002/86; C01P 2004/32; C01P 2004/50; C01P 2004/84; C01P 2006/40

(57) ABSTRACT

The invention generally relates to new electron spin containing materials and in particular methods of preparing such materials in order to spatially separate electron spins from atmospheric oxygen and moisture.

### FIELD

The invention generally relates to new electron spin containing materials and in particular methods of preparing such materials in order to spatially separate electron spins from atmospheric oxygen and moisture.

### BACKGROUND

Computer systems comprise signal lines to carry information and memory capacitors to store information. A voltage source charges and discharges the signal lines and memory capacitors in order to represent information. For example, a voltage of +5V on a signal line or memory capacitor represents a logical “1” and a voltage of OV represents a logical “0”. Changing a bit between “0” and “1” involves the transport of electronic charge in the form of a large number of electrons.

A more powerful way to represent information is to use the spin of a single electron. The electron spin represents a two-state quantum mechanical system, which is the basic building block of a quantum computer. For instance, fullerene-based electron spin quantum devices, wherein the fullerene molecules are in the form of hollow carbon spheres, are known in the art.

One of the biggest practical problems in using electron spin is that its lifetime (T_{S}) is typically too short for application at room-temperature. One solution to achieve a longer lifetime is to cool the quantum mechanical system to below 4K. This leads to T_{S} exceeding 100 ns. Such a long lifetime allows the manipulation of electron spin together with the motion of charge to perform multiple operations. However this cooling requirement is impractical for commercially distributed products since these products would be too large and heavy, expensive (high capital expenditure) and consume too much energy for home, office and mobile applications.

Furthermore, electron spins in materials exposed to molecular oxygen (O₂) either through air or moisture exposure have lifetimes that are significantly shorter than when measured under vacuum, due to them coupling with the unpaired electrons in molecular oxygen. This effect has been reported previously in the literature on Electron Spin Resonance (ESR) in carbon-based materials. The increased cw-ESR linewidths (corresponding to decreased electron spin lifetimes) are the result of either the Heisenberg exchange interaction, or spin dipole-dipole interactions, or a combination of both.

The instant invention provides for new materials containing electron spins to be measured without the need for a vacuum, with lifetimes comparable to those expected in vacuum or under high-purity inert gas atmosphere.

### SUMMARY OF INVENTION

The invention is predicated in part on the discovery that gas-impermeable compounds such as oxides or nitrides could be applied as encapsulation ingredients to specific electron spin containing material and that the encapsulation ingredient may act as a so called ‘virtual vacuum’ leading to maintaining electron spin lifetimes (of the resulting encapsulated product) that is closer to their vacuum value, even when measured under ambient atmosphere.

The present invention is specifically directed to the encapsulation of carbon nanospheres (CNS). “Carbon nano onions” (CNO) or “onion like carbon” (OLC), which are carbonaceous nanostructures typically of about 10⁻¹⁰⁰ nm in size composed of multiple concentric shells of graphene and/or graphite sheets or fragments, and also often referred to as CNS. The individual graphitic and/or graphene sheets or fragments in the carbon nanospheres are not curved and do not resemble the curvature of nanotubes or fullerenes. Rather, the fragments/sheets exhibit an intricate array of interplanar bonding all the way to the centre of the nanosphere even when heated to temperatures of about 583 K. Unlike fullerenes and carbon nanotubes, carbon nanospheres are not hollow or tubular in nature but instead show a continuation of the closed cage structure towards the centre. The skilled person understands that CNS are not in reality perfectly spherical but can be described as sphere like. This has been confirmed by transmission electron microscopy.

In general however CNS are a class of nanomaterials that can exhibit long electron spin relaxation times at room temperature under various atmospheres and thus hold promise as potential building blocks for spintronics and quantum information processing devices. Accordingly, in relation to the present invention, ‘carbon nanosphere’ refers not just to a carbon nanoparticle with a spherical like shape, but to a solid, metallic-like carbon nanomaterial with a special structure and unique electron spin properties. As detailed below the CNS of the present invention are synthesized by the combustion of polyaromatic hydrocarbons in air. The ‘gas impermeable’ coating is then produced via Atomic Layer Deposition (ALD) and/or Plasma-Enhanced Chemical Vapour Deposition (PECVD), followed by an annealing process in a high-vacuum environment. This coating is designed to create conditions similar to a vacuum to protect the electron spins within the core material for applications in quantum spintronic and quantum processing devices.

In certain embodiments the CNS as used in the present invention is not hollow and the CNS comprises metallic electron spin states delocalised over the volume of the CNS, the electron spin states being itinerant in nature optionally with electron spin lifetimes at room-temperature of approximately 115 nanoseconds, and said CNS further comprising short graphitic fragments that form unclosed shells following curvature of a sphere.

In certain other embodiments the CNS used in the present invention has a diameter of between 20 nm and 55 nm, is not hollow and comprises short graphitic fragments that form unclosed shells following the curvature of the nanosphere, the carbon nanosphere exhibiting an intricate array of interplanar bonding all the way to the centre of the nanosphere, thereby resulting in a conducting homogeneous material that is structurally highly non-crystalline (ie amorphous), the carbon nanosphere thereby possessing metallic electron spin states delocalised over the entire diameter of the carbon nanosphere, the electron spin states being itinerant in nature optionally with electron spin lifetimes at room temperature of approximately 115 nanoseconds.

In relation to the differences in spin properties between CNS and other systems (including fullerenes) we refer the reader to Nafradi et al, Nature Communications, 7, Article Number, 12232, (2016). Diagram 1 of Nafradi et al (below): Compares the itinerant and localized electron-based qubits including the metallic-like carbon nanospheres (a) used in the present invention.

In the above diagram (a) represents the itinerant spin system of the proposed carbon nanospheres (CNS) which are subject of the present invention. The shaded circle denotes that the electrons are delocalised (itinerant) over the entire system. This is to be contrasted with the localised systems of (b) N@C60 (Fullerene), (c) N-V nanodiamond and (d) Si: P. The spin information in the CNS is encoded by a delocalised electron spin that spreads over the entire diameter making the system more robust against external magnetic field fluctuations and hyperfine interactions enforced by nuclear spins. As such, high qubit density can be achieved without enhanced decoherence. Section (e) shows the sphere diameters comparing the required volume for different types of qubits with scale bar (100 nm).

The important difference between the teaching of Nafradi et al is that the CNS particles of the present invention are encapsulated with a coating layer, whereby ESR is measured in atmosphere, and the quantum device made from this encapsulated CNS particles can operate in atmosphere rather than under vacuum as they retain electron spin lifetimes which are similar to or close to the spin lifetimes as measured under vacuum and at room temperature.

For instance, in certain embodiments the variation in spin lifetimes, as measured by cw-ESR linewidth in Gauss, between the encapsulated CNS particles of the present invention under vacuum relative and under atmospheric conditions is only about 0.01-0.5 Gauss. Typically, in certain embodiments, the unmodified CNS particles encapsulated with silicon nitride and sealed in a vacuum is characterised with a linewidth of about 0.97 Gauss, which when the seal is broken (ie the particles are exposed to the atmosphere) one observes line broadening to only about 1.2 Gauss (i.e., a variation of only 0.23 Gauss).

The skilled person would understand that one may convert the linewidth ESR measurement to an actual T1 and T2 nanosecond lifetime measurement such as that described in Poole Jr, C. P. & Farach, H. A. in Relaxation in Magnetic Resonance (eds Charles P. Poole & Horacio A. Farach) 17-29 (Academic Press, 1971) incorporated herein by reference in its entirety.

For instance, 0.97 Gauss is ~67.57 ns, and 1.2 Gauss is ~54.62 ns.

In one aspect the invention provides individual encapsulated carbon nanosphere particles or an agglomeration thereof, comprising a carbon nanosphere core and an encapsulating outer coating layer comprising one or more gas-impermeable compounds, wherein the coating layer has a thickness of about 5-50 nm, and further wherein the encapsulated carbon nanosphere particles or an agglomeration thereof is optionally bound to a solid substrate surface.

In a further aspect the invention provides encapsulated carbon nanosphere particles comprising a carbon nanosphere core and an encapsulating outer coating layer comprising one or more gas-impermeable compounds, wherein the coating layer has a thickness of about 5-50 nm.

In another aspect the invention provides an encapsulated agglomeration of carbon nanosphere particles of from 2-100 billion carbon nanosphere particles comprising an carbon nanosphere core and an encapsulating outer coating layer comprising one or more gas-impermeable compounds, wherein the coating layer has a thickness of about 5-50 nm.

### BRIEF DESCRIPTION OF FIGURES

FIG. 1. Continuous-wave (CW) ESR spectra of encapsulated CNS samples both sealed in vacuum and unsealed, accompanied by Lorentzian+Gaussian fits and fitting parameters inset. a) Sample encapsulated in ~20 nm of aluminium oxide and sealed in vacuum showing a linewidth of ~0.940 Gauss b) The same sample after breaking the vacuum seal, showing an essentially unchanged linewidth of ~0.935 Gauss c) Sample encapsulated in ~50 nm of silicon nitride and sealed in vacuum showing a linewidth of ~0.971 Gauss d) The same sample after breaking the vacuum seal, showing a broadened linewidth of ~1.22 Gauss.

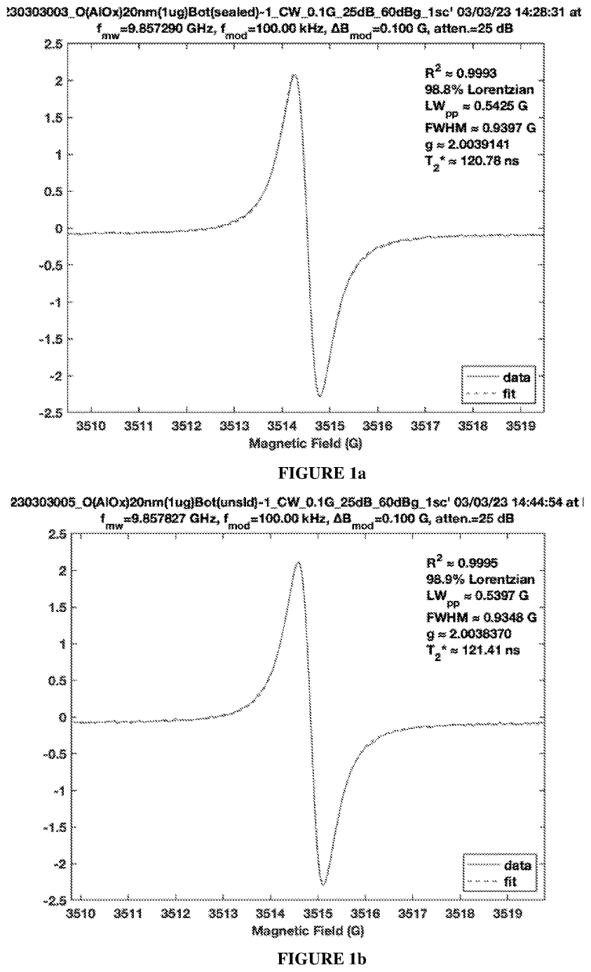

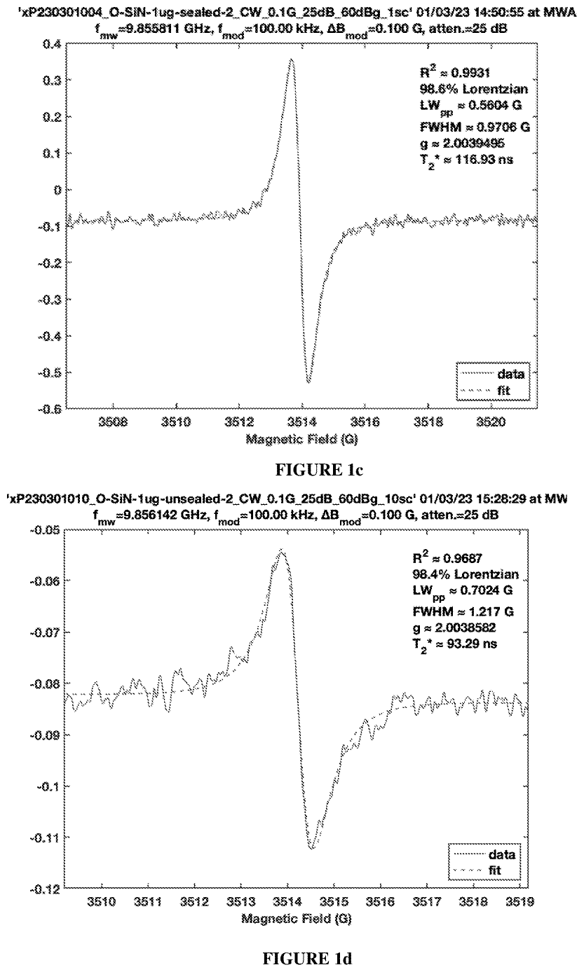

### DETAILED DESCRIPTION

In certain embodiments the invention provides carbon nanospheres and/or carbon nanosphere agglomerates, where the individual carbon nanospheres, or the agglomerates, have been fully or substantially encapsulated by gas-impermeable compounds such as oxides or nitrides. Accordingly, it will be appreciated that the present invention contemplates the encapsulation of either individual carbon nanospheres particles, or agglomerates comprising from 2-100 billion carbon nanospheres particles.

In certain embodiments, the CNS particle is a doped or undoped CNS particle, which is subsequently encapsulated.

The CNS particles may be doped with one or more heteroatoms, including but not limited to boron, nitrogen, oxygen, fluorine, silicon, phosphorus, sulphur, and selenium. Doping has been a widely utilized strategy to modify the properties of pristine carbon-based materials, particularly their electronic structures. The doping can be achieved via various methodologies such as chemical vapor deposition (CVD), chemical doping, ball-milling, ultraviolet (UV) or microwave treatment, and electrochemical approaches. (Refs: Kim et al Scientific Reports 7, Article number 14400 (2017), Ahmed et al General Doping Chemistry of Carbon Materials, Chemnanomat, Vol 9, Issue 4, April 2023 and Hao et al J. Mater. Chem. A, 2018, 6, 8053-8058).

In other embodiments the invention provides quantum electronic device components which comprises said encapsulated carbon nanospheres or agglomerates adapted to store a qubit represented by an electron spin; and a control and readout device to set the qubit and read the qubit stored on said encapsulated carbon nanospheres or agglomerates.

In other embodiments, the invention provides a quantum electronic device comprising:
individual encapsulated carbon nanosphere (CNS) particles or an agglomeration thereof as mentioned herein, adapted to store a qubit represented by an electron spin;
and
a control and readout device to set the qubit and read the qubit stored on the carbon nanosphere or agglomeration thereof, wherein the individual carbon nanosphere particles have a diameter of between 20 nm and 55 nm, are not hollow and comprise short graphitic fragments that form unclosed shells following the curvature of the nanosphere, the carbon nanosphere exhibiting an intricate array of interplanar bonding all the way to the centre of the nanosphere, thereby resulting in a conducting homogeneous material that is structurally highly non-crystalline, the individual carbon nanosphere particles or agglomeration thereof thereby possessing metallic electron spin states delocalised over the entire diameter of the individual carbon nanosphere particles, the electron spin states being itinerant in nature optionally with electron spin lifetimes at room temperature of approximately 115 nanoseconds.

In certain other embodiments the electron spin states being itinerant in nature with electron spin lifetimes at room temperature of approximately 115 nanoseconds, and wherein the variation in spin lifetimes, as measured by cw-ESR linewidth in Gauss, between the encapsulated CNS particles of the present invention under vacuum relative to under atmospheric conditions is only about 0.05-0.5 Gauss.

It is an advantage that the qubits stored on the encapsulated carbon nanospheres or agglomerates have a long electron spin lifetime at room temperature and under atmospheric conditions. For instance, the electronic spins lifetimes of uncoated (and undoped) CNS of Nafradi et al are approximately 115 nanoseconds under vacuum but this is substantially diminished (as low as 2-5 nanoseconds) once exposed to the atmosphere. This is thought to occur not only because of the pressure differential but also due to exposure to atmospheric oxygen and moisture.

In certain embodiments, the one or more gas-impermeable compound is selected from the group consisting aluminium oxide, silicon nitride, silicon dioxide. silicon carbide, aluminium nitride, aluminium oxynitride, titanium oxynitride, titanium dioxide, is titanium nitride, and boron nitride. In an embodiment the one or more gas-impermeable compound is aluminium oxide.

In an embodiment the one or more gas-impermeable compound is silicon nitride.

In an embodiment the one or more gas-impermeable compound is silicon dioxide.

In an embodiment the one or more gas-impermeable compound is silicon carbide.

In an embodiment the one or more gas-impermeable compound is aluminium nitride.

In an embodiment the one or more gas-impermeable compound is aluminium oxynitride.

In an embodiment the one or more gas-impermeable compound is titanium oxynitride.

In an embodiment the one or more gas-impermeable compound is titanium dioxide.

In an embodiment the one or more gas-impermeable compound is titanium nitride.

In an embodiment the one or more gas-impermeable compound is boron nitride.

In specific embodiments the encapsulation is a single-layer encapsulation using a single encapsulation gas-impermeable compound as referred to above. In an embodiment the encapsulated carbon nanosphere particles or agglomerates of the invention are characterised with electron spin resonance under non-vacuum, ambient atmosphere with a difference of only between about 0.01-0.5 or about 0-0.250 Gauss relative to same unencapsulated carbon nanosphere particles or agglomerates under vacuum conditions at the same temperature.

In an embodiment the encapsulated carbon nanosphere particles or agglomerates of the invention are characterised with electron spin lifetimes with a difference of only between about 0-30 ns relative to same unencapsulated carbon nanosphere particles under vacuum conditions at the same temperature.

Accordingly, in still a further aspect the invention provides a method of preparing encapsulated carbon nanospheres, said method comprising:
1) dispersing a quantity of carbon nanospheres in a non-polar solvent;
2) coating said carbon nanospheres with a gas-impermeable encapsulation compound to produce encapsulated carbon nanospheres with a coating layer of from about 5-50 nm thickness; and
3) subjecting the encapsulated carbon nanospheres to an annealing process in order to evacuate any trapped gases from the coating layer of the encapsulated carbon nanospheres.

In certain embodiments, the non-polar solvent is selected from the group consisting of pentane, hexane, heptane, benzene, toluene and xylene.

In certain embodiments, the non-polar solvent is toluene.

In certain embodiments, the dispersion step involves about 1 mg/mL to about 10 mg/mL of the carbon nanospheres in the non-polar solvents.

In an embodiment the annealing process is performed at from about 150-250° C. for about 20-60 minutes under high vacuum (~10⁻⁴ to ~10⁻⁷ mBar).

In an embodiment the annealing process is performed at from about 150-250° C. for about 20-40 minutes under high vacuum (~10⁻⁶ mBar).

In certain embodiments the carbon nano spheres may characterised with sphere diameter of from 20-200 nm. Larger sphere diameters may result in longer spin lifetime. Accordingly, in certain embodiments the sphere diameter may be around 50-150 nm.

In still a further aspect the invention provides encapsulated carbon nanosphere particles comprising a carbon nanosphere core and an encapsulating outer coating layer comprising one or more gas-impermeable compounds, wherein the coating layer has a thickness of about 5-50 nm, and further wherein the encapsulated carbon nanosphere particles are bound to a solid substrate surface.

In another aspect the invention provides an encapsulated agglomeration of carbon nanosphere particles comprising 2-100 billion carbon nanosphere cores and an encapsulating outer coating layer comprising one or more gas-impermeable compounds, wherein the coating layer has a thickness of about 5-50 nm, and further wherein the encapsulated carbon nanosphere agglomeration are bound to a solid substrate surface.

In certain embodiments the substrate surface is quartz (SiO₂), GaAs, AlGaAs, InGaAs, InAsSbP, Si, Silicon on Insulator (SOI), Al₂O₃ (sapphire), polytetrafluoroethylene (PTFE), polyether ether ketone (PEEK) or another semicrystalline thermoplastic substrate material.

Accordingly, in still a further aspect the invention provides a method of preparing encapsulated carbon nanospheres bound to a solid substrate, said method comprising:
1) dispersing a quantity of carbon nanospheres in toluene;
2) depositing a quantity of the dispersion from 1) on a solid substrate which has been pre-treated by:
   a. cleaning with acetone, then isopropyl (IPA), and then dried with an inert gas; and
   b. oxygen plasma ashing at a pressure of from about 300-450 mTorr;
      in order to form a carbon nanosphere deposit on said solid substrate;
3) coating said deposit from step 2) with a gas-impermeable encapsulation compound to produce encapsulated carbon nanospheres with a coating layer of from about 5-50 nm thickness; and
4) subjecting the encapsulated carbon nanospheres bound to a solid support to an annealing process in order to evacuate any trapped gases from the coating layer of the encapsulated carbon nanospheres.

In an embodiment the dispersion of step 2) is a toluene dispersion of from about 1 mg/mL to about 10 mg/mL of the carbon nanospheres.

In an embodiment the solid substrate surface is a quartz slide which has diced to fit into a 4 mm ESR tube prior to step 2).

In an embodiment the oxygen plasma ashing process is a 5-minute process performed at a pressure of about 300-450 mTorr, and a power of about 50 W in a O₂ Plasma Asher Glow (Plasma O₂) to remove any remaining organic matter.

In an embodiment the annealing process is performed at from about 150-250° C. for about 20-40 minutes under high vacuum (~10⁻⁶ mBar) inside the quartz ESR tube that the samples maybe later measured in.

In certain embodiments the carbon nano spheres may characterised with sphere diameter of from 20-200 nm. Larger sphere diameters may result in longer spin lifetime. Accordingly, in certain embodiments the sphere diameter may be around 50-150 nm.

The present invention also provides a quantum electronic device comprising:
individual encapsulated carbon nanosphere (CNS) particles or an agglomeration thereof according to the present invention, adapted to store a qubit represented by an electron spin;
and
a control and readout device to set the qubit and read the qubit stored on the carbon nanosphere or agglomeration thereof, wherein the individual carbon nanosphere particles have a diameter of between 20 nm and 55 nm, are not hollow and comprise short graphitic fragments that form unclosed shells following the curvature of the nanosphere, the carbon nanosphere exhibiting an intricate array of interplanar bonding all the way to the centre of the nanosphere, thereby resulting in a conducting homogeneous material that is structurally highly non-crystalline, the individual carbon nanosphere particles or agglomeration thereof thereby possessing metallic electron spin states delocalised over the entire diameter of the individual carbon nanosphere particles, the electron spin states being itinerant in nature, optionally with electron spin lifetimes at room temperature of approximately 115 nanoseconds.

In certain embodiments, the individual carbon nanosphere particles have a diameter of 35 nm.

In certain embodiments, the quantum electronic device has the carbon nanosphere particles or agglomeration thereof at a temperature between-40 degrees Celsius and +40 degrees Celsius.

In certain embodiments, the quantum electronic device is a spintronic device having multiple of the encapsulated carbon nanospheres each of which being adapted to provide a qubit represented by an electron spin in that carbon nanosphere;
and the control device is to facilitate interaction between the qubits on the multiple encapsulated carbon nanospheres to perform a quantum operation.

In certain embodiments, the quantum electronic device further comprises a conductor coupled to the carbon nanospheres to provide transport of electrons that carry the electron spin.

In certain embodiments, the conductor comprises a graphene structure.

In certain embodiments, the quantum electronic device further comprises an electrode associated with each of the multiple encapsulated carbon nanospheres.

In certain embodiments, the quantum electronic device further comprises an isolation layer to isolate the electrodes from the multiple encapsulated carbon nanospheres.

In certain embodiments, the isolation layer has a thickness between 200 nm to 400 nm.

In certain embodiments, the isolation layer comprises an SiO₂ layer.

In certain embodiments, the distance between the multiple encapsulated carbon nanospheres is such that the spin is not lost during transport between the multiple encapsulated carbon nanospheres.

In certain embodiments, the distance between the multiple encapsulated carbon nanospheres is between 50 nm and 1,000 nm.

In certain other embodiments, the invention contemplates the use of an encapsulated carbon nanosphere of the present invention for the fabrication of the quantum electronic device.

And finally, the invention also contemplates a method for quantum computing, the method comprising:
storing a qubit represented by an electron spin on the individual encapsulated carbon nanosphere particles or agglomeration thereof of the quantum electronic device according to the present invention;
and
performing a quantum operation on the qubit to generate a resulting qubit; and reading the resulting qubit from the individual encapsulated carbon nanosphere or agglomeration thereof.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

The invention will now be described with reference to the following non-limiting examples.

### EXAMPLES

### Preparation CNS

The synthesis of carbon nanospheres may involve a flash pyrolysis of a polyaromatic hydrocarbon vapor, such as naphthalene or others, onto a glass or ceramic substrate. This may involve continuous ignition of the vapor resulting from heating 0.5 g of naphthalene (M&B Chemicals) to its flashpoint (ca. 79-87° C.) in air, using an open flame. The carbon material may be collected on a glass or ceramic dish, and any remaining naphthalene may be removed by heating the sample in a vacuum oven at 200° C. for 24 h. The synthesis may yield 0.4 g of CNS flakes per hour (20% carbon recovery). The sample may be heated up to 600° C. under dynamic vacuum for 12 h.

### Sample Preparation and Encapsulation Process

Samples were prepared for encapsulation by preparing a dispersion of the CNS material in Toluene with a concentration of 2 mg/mL. Quartz slides were diced to fit into 4 mm ø ESR tubes and cleaned with acetone, isopropyl alcohol (IPA) and a nitrogen gun for drying. A 5-minute oxygen plasma ash was then performed at a pressure of 350-400 mTorr, and a power of 50 W in a O₂ Plasma Asher Glow (Plasma O₂) to remove any remaining organic matter. A 0.5 μL drop was then cast onto each quartz slide using a mechanical pipette in a cleanroom environment.

Deposition of aluminium oxide was performed using a PicoSun R200 Atomic Layer Deposition (ALD) system using trimethyl aluminium and water, at 150° C. and 5-6 mTorr for around 250 cycles to achieve a 20 nm oxide thickness.

Alternatively, deposition of silicon nitride (SiN) was performed in an Oxford Instruments PlasmaPro 100 PECVD module using silane (SiH₄), ammonia (NH₃) and nitrogen (N₂) precursors at 300° C. and 650 mTorr for around one minute per 15.3 nanometres of layer thickness.

After deposition, the sample was again plasma ashed using the same settings as mentioned earlier, to ensure any CNS material that was not encapsulated is removed.

After encapsulation, the samples were subjected to a post-deposition anneal (PDA) to ensure that any trapped gases are diffused out of the encapsulating layer. This anneal was performed at 200° C. for 20-40 minutes under high vacuum (~10⁻⁶ mBar) inside the quartz ESR tube that the samples are later measured in.

For baseline measurements, the sample was then sealed under vacuum in the ESR tube. The quality of the encapsulation was then determined by how minimal the broadening of the ESR linewidth was when the sealed sample was compared to the same (or similar) samples measured ‘unsealed’—i.e. without vacuum. ESR linewidths were measured in a Bruker EMXPlus EPR Spectrometer at X-band (~9.6 GHz) and at room temperature.

### Synthesis of B-doped CNS

For the synthesis of boron-doped CNS, a typical procedure involves the following steps: 1.5 mg of pristine CNS, as prepared previously, is mixed with 2.5 mg of boric acid via mechanical milling. The mixture is then sealed in a quartz tube (4 mm diameter, 250 mm length) under vacuum conditions. This sealed tube is annealed at 900° C. for 2 hours in a vacuum tube furnace. After the annealing process, the powder sample is washed and dried, rendering it ready for further characterization.

The claims defining the invention are as follows:

1. Individual encapsulated carbon nanosphere (CNS) particles or an agglomeration thereof, comprising a carbon nanosphere core and an encapsulating outer coating layer comprising one or more gas-impermeable compounds, wherein the coating layer has a thickness of about 5-50 nm, and further wherein the encapsulated carbon nanosphere particles or an agglomeration thereof is optionally bound to a solid substrate surface.

2. Individual encapsulated carbon nanosphere (CNS) particles or an agglomeration thereof according to claim 1 wherein the CNS particles are synthesized by the combustion of polyaromatic hydrocarbons in air.

3. Individual encapsulated carbon nanosphere (CNS) particles or an agglomeration thereof according to claim 1 or 2 wherein the coating layer is produced via Atomic Layer Deposition (ALD) and/or Plasma-Enhanced Chemical Vapour Deposition (PECVD), followed by an annealing process in a high-vacuum environment.

4. Individual encapsulated carbon nanosphere (CNS) particles or an agglomeration thereof according to anyone of claims 1 to 3 wherein the CNS particles have a diameter of between 20 nm and 55 nm.

5. Individual encapsulated carbon nanosphere particles or an agglomeration thereof according to any one of claims 1 to 3 comprising a carbon nanosphere core and an encapsulating outer coating layer comprising one or more gas-impermeable compounds, wherein the coating layer has a thickness of about 5-50 nm, and wherein the individual carbon nanosphere particles or agglomeration thereof thereby possesses metallic electron spin states delocalised over the entire diameter of the individual carbon nanosphere particles.

6. Individual encapsulated carbon nanosphere particles or an agglomeration thereof according to claim 5 with the electron spin states being itinerant in nature with electron spin lifetimes at room temperature of approximately 115 nanoseconds.

7. Individual encapsulated carbon nanosphere particles or an agglomeration thereof according to any one of claims 1 to 6 comprising a doped carbon nanosphere.

8. Individual encapsulated carbon nanosphere particles or an agglomeration thereof according to claim 7 wherein the dopant is selected from boron, nitrogen, oxygen, fluorine, silicon, phosphorus, sulphur, and selenium.

9. Individual encapsulated carbon nanosphere particles or an agglomeration thereof according to claim 6 wherein the dopant is boron.

10. Individual encapsulated carbon nanosphere particles or an agglomeration thereof according to any one of claims 1 to 5 comprising an undoped carbon nanosphere.

11. An encapsulated agglomeration of carbon nanosphere particles according to anyone of claims 1 to 10 comprising 2-100 billion carbon nanosphere particles comprising carbon nanosphere cores and an encapsulating outer coating layer comprising one or more gas-impermeable compounds, wherein the coating layer has a thickness of about 5-50 nm.

12. Encapsulated carbon nanosphere particles according to claim 1 comprising a carbon nanosphere core and an encapsulating outer coating layer comprising one or more gas-impermeable compounds, wherein the coating layer has a thickness of about 5-50 nm, and further wherein the encapsulated carbon nanosphere particles are bound to a solid substrate surface.

13. An encapsulated agglomeration of carbon nanosphere particles according to claim 1 comprising 2-100 billion carbon nanosphere particles comprising carbon nanosphere cores and an encapsulating outer coating layer comprising one or more gas-impermeable compounds, wherein the coating layer has a thickness of about 5-50 nm, and further wherein the encapsulated carbon nanosphere agglomeration are bound to a solid substrate surface.

14. A quantum electronic device component which comprises encapsulated carbon nanosphere particles or agglomerates according to anyone of claims 1 to 13 adapted to store a qubit represented by an electron spin; and a control and readout device to set the qubit and read the qubit stored on said encapsulated carbon nanospheres or agglomerates.

15. An encapsulated carbon nanosphere particle or agglomerates according to anyone of claims 1 to 14 which are characterised with electron spin lifetimes with a difference of between about 0-30 ns relative to unencapsulated carbon nanosphere particles or agglomerates under vacuum conditions at the same temperature.

16. An encapsulated carbon nanosphere particle or agglomerates according to claim 12 or 13 wherein the substrate surface is quartz (SiO₂), GaAs, AlGaAs, InGaAs, InAsSbP, Si, Silicon on Insulator (SOI), Al₂O₃ (sapphire), polytetrafluoroethylene (PTFE), polyether ether ketone (PEEK) or another semicrystalline thermoplastic substrate material.

17. An encapsulated carbon nanosphere particle or agglomerate according to anyone of claims 1 to 16, wherein the one or more gas-impermeable compound is aluminium oxide.

18. An encapsulated carbon nanosphere particle or agglomerate according to anyone of claims 1 to 16, wherein the one or more gas-impermeable compound is silicon nitride.

19. An encapsulated carbon nanosphere particle or agglomerate according to anyone of claims 1 to 16, wherein the one or more gas-impermeable compound is silicon dioxide.

20. An encapsulated carbon nanosphere particle or agglomerate according to anyone of claims 1 to 16, wherein the one or more gas-impermeable compound is silicon carbide.

21. An encapsulated carbon nanosphere particle or agglomerate according to anyone of claims 1 to 16, wherein the one or more gas-impermeable compound is aluminium nitride.

22. An encapsulated carbon nanosphere particle or agglomerate according to anyone of claims 1 to 16, wherein the one or more gas-impermeable compound is aluminium oxynitride.

23. An encapsulated carbon nanosphere particle or agglomerate according to anyone of claims 1 to 16, wherein the one or more gas-impermeable compound is titanium oxynitride.

24. An encapsulated carbon nanosphere particle or agglomerate according to anyone of claims 1 to 16, wherein the one or more gas-impermeable compound is titanium dioxide.

25. An encapsulated carbon nanosphere particle or agglomerate according to anyone of claims 1 to 16, wherein the one or more gas-impermeable compound is titanium nitride.

26. An encapsulated carbon nanosphere particle or agglomerate according to anyone of claims 1 to 16, wherein the one or more gas-impermeable compound is boron nitride.

27. An encapsulated carbon nanosphere particle or agglomerate according to anyone of claims 1 to 26, wherein encapsulation is a single-layer encapsulation using a single gas-impermeable compound.

28. An encapsulated carbon nanosphere particles or agglomerates according to anyone of claims 1 to 27 characterised with electron spin resonance under non-vacuum, ambient atmosphere with a difference of only between about 0.01-0.5 Gauss relative to same unencapsulated carbon nanosphere particles or agglomerates under vacuum conditions at the same temperature.

29. An encapsulated carbon nanosphere particles or agglomerates according to anyone of claims 1 to 27 characterised with electron spin resonance under non-vacuum, ambient atmosphere with a difference of only between about 0-0.250 Gauss relative to same unencapsulated carbon nanosphere particles or agglomerates under vacuum conditions at the same temperature.

30. A method of preparing encapsulated carbon nanospheres bound to a solid substrate, said method comprising:
1. dispersing a quantity of carbon nanospheres in toluene;
2. depositing a quantity of the dispersion from 1) on a solid substrate which has been pre-treated by:
a. cleaning with acetone, then isopropyl (IPA), and then dried with an inert gas; and
b. oxygen plasma ashing at a pressure of from about 300-450 mTorr;
in order to form a carbon nanosphere deposit on said solid substrate;
3. coating said deposit from step 2) with a gas-impermeable encapsulation compound to produce encapsulated carbon nanospheres with a coating layer of from about 5-50 nm thickness; and
4. subjecting the encapsulated carbon nanospheres bound to a solid support to an annealing process in order to evacuate any trapped gases from the coating layer of the encapsulated carbon nanospheres.

31. A method according to claim 30 wherein the dispersion of step 2) is a toluene dispersion of from about 1 mg/mL to about 10 mg/mL of the carbon nanospheres.

32. A method according to claim 30 or 31 wherein the oxygen plasma ashing process is a 5-minute process performed at a pressure of about 300-450 mTorr, and a power of about 50 W in a O₂ Plasma Asher Glow (Plasma O₂) to remove any remaining organic matter.

33. A method according to anyone of claims 30 to 32 wherein the annealing process is performed at from about 150-250° C. for about 20-40 minutes under high vacuum (~10⁻⁶ mBar) inside the quartz ESR tube that the samples maybe later measured in.

34. A method of preparing encapsulated carbon nanospheres, said method comprising:
1. dispersing a quantity of carbon nanospheres in a non-polar solvent;
2. coating said carbon nanospheres with a gas-impermeable encapsulation compound to produce encapsulated carbon nanospheres with a coating layer of from about 5-50 nm thickness; and
3. subjecting the encapsulated carbon nanospheres to an annealing process in order to evacuate any trapped gases from the coating layer of the encapsulated carbon nanospheres.

35. A method according to claim 33 wherein the non-polar solvent is selected from the group consisting of pentane, hexane, heptane, benzene, toluene and xylene.

36. A method according to claim 35 wherein the non-polar solvent is toluene.

37. A method according to claim 35 or 36 wherein the dispersion step involves about 1 mg/mL to about 10 mg/mL of the carbon nanospheres in the non-polar solvents.

38. A method according to anyone of claims 34 to 37 In an embodiment the annealing process is performed at from about 150-250° C. for about 20-60 minutes under high vacuum (~10⁻⁴ to ~10⁻⁷ mBar).

39. A method according to anyone of claims 34 to 37 claim In an embodiment the annealing process is performed at from about 150-250° C. for about 20-40 minutes under high vacuum (~10⁻⁶ mBar).

40. An encapsulated carbon nanosphere particle or agglomerate or method according to anyone of claims 1 to 39 wherein the carbon nano spheres are characterised with an approximate sphere diameter of from 20-200 nm.

41. An encapsulated carbon nanosphere particle or agglomerate or method according to claim 38 wherein the carbon nano spheres are characterised with an approximate sphere diameter may be around 50-150 nm.

42. A quantum electronic device comprising:
individual encapsulated carbon nanosphere (CNS) particles or an agglomeration thereof according to anyone of claim 1 to 29 or 41, adapted to store a qubit represented by an electron spin;
and
a control and readout device to set the qubit and read the qubit stored on the carbon nanosphere or agglomeration thereof, wherein the individual carbon nanosphere particles have a diameter of between 20 nm and 55 nm, are not hollow and comprise short graphitic fragments that form unclosed shells following the curvature of the nanosphere, the carbon nanosphere exhibiting an intricate array of interplanar bonding all the way to the centre of the nanosphere, thereby resulting in a conducting homogeneous material that is structurally highly non-crystalline, the individual carbon nanosphere particles or agglomeration thereof thereby possessing metallic electron spin states delocalised over the entire diameter of the individual carbon nanosphere particles, the electron spin states being itinerant in nature, optionally with electron spin lifetimes at room temperature of approximately 115 nanoseconds.

43. The quantum electronic device of claim 42, wherein the individual carbon nanosphere particles have a diameter of 35 nm.

44. The quantum electronic device of claims 42 and 43, wherein the carbon nanosphere particles or agglomeration thereof is at a temperature between-40 degrees Celsius and +40 degrees Celsius.

45. A method for quantum computing, the method comprising:
storing a qubit represented by an electron spin on the individual encapsulated carbon nanosphere particles or agglomeration thereof of the quantum electronic device according to any one of claim 1 to 29 or 41;
performing a quantum operation on the qubit to generate a resulting qubit; and reading the resulting qubit from the individual encapsulated carbon nanosphere or agglomeration thereof.

46. The quantum electronic device according to any one of claims 40 to 42 wherein the quantum electronic device is a spintronic device having multiple of the encapsulated carbon nanospheres each of which being adapted to provide a qubit represented by an electron spin in that carbon nanosphere;
and the control device is to facilitate interaction between the qubits on the multiple encapsulated carbon nanospheres to perform a quantum operation.

47. The quantum electronic device of claim 46 further comprising a conductor coupled to the carbon nanospheres to provide transport of electrons that carry the electron spin.

48. The quantum electronic device of claim 47, wherein the conductor comprises a graphene structure.

49. The quantum electronic device of claim 47 or 48 further comprising an electrode associated with each of the multiple encapsulated carbon nanospheres.

50. The quantum electronic device of claim 49, further comprising an isolation layer to isolate the electrodes from the multiple encapsulated carbon nanospheres.

51. The quantum electronic device of claim 50, wherein the isolation layer has a thickness between 200 nm to 400 nm.

52. The quantum electronic device of claim 50 or 51, wherein the isolation layer comprises an SiO₂ layer.

53. The quantum electronic device any one of claims 42 to 44, 45 to 52, wherein a distance between the multiple encapsulated carbon nanospheres is such that the spin is not lost during transport between the multiple encapsulated carbon nanospheres.

54. The quantum electronic device of claim 53, wherein the distance between the multiple encapsulated carbon nanospheres is between 50 nm and 1,000 nm.

55. Use of an encapsulated carbon nanosphere for the fabrication of the quantum electronic device of any one of claims 42 to 44, 46 to 54.
